(19) United States
(12) Patent Application Publication
(10) Pub. No.: US 2007/0268037 A1
(43) Pub. Date: Nov. 22, 2007

(54) CIRCUIT TESTING APPARATUS

(76) Inventors: Cheng-Yung Teng, Taipei County (TW); Yi-Chang Hsu, Taipei County (TW); Wei-Fen Chiang, Taipei City (TW); Hung-Wei Chen, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/608,226

(22) Filed: Dec. 7, 2006

(30) Foreign Application Priority Data
May 22, 2006 (TW) 095208770

(51) Int. Cl. G01R 31/26

(52) U.S. Cl. 324/765

(57) ABSTRACT

The present invention discloses a circuit testing apparatus for testing a device under test. The circuit testing apparatus includes a signal transformation module, a meter, and a logic tester. The signal transformation module is coupled to the device under test and transforms an analog output signal generated by the device under test into a DC signal. The meter is coupled to the signal transformation module and measures the DC signal so as to generate a digital measuring result. The logic tester is coupled to the meter and determines a test result for the device under test according to the digital measuring result.

### BACKGROUND OF THE INVENTION

1. Field of the Invention

The present invention relates to circuit testing, and more particularly, to a circuit testing apparatus that includes a logic tester and allows analog-signal circuits or mixed-signal circuits to be tested.

2. Description of the Prior Art

Generally speaking, Integrated Circuits (ICs) available on the market can be categorized into analog-signal ICs, digital-signal ICs, and mixed-signal ICs. A mixed-signal IC is an IC integrated with analog circuitry and logic circuitry and allows both analog signals and logic signals to be processed. No matter what category a manufactured IC belongs to, it has to be put through various tests. The manufacturer determines whether an IC is qualified for being sold according to the test results.

FIG. 1 shows a conventional circuit testing structure. In this structure, a mixed-signal tester 140 is utilized as a tool for testing a device under test (DUT) 110. The DUT 110 may be an analog-signal IC or a mixed-signal IC. For convenience, the DUT 110 is normally set on a DUT board 120 before the test is performed.

Generally speaking, the mixed-signal tester 140 comprises a digital signal processor (DSP) 150, an analog-to-digital converter (ADC) 160, and an arbitrary waveform generator (AWG) 170. The AWG 170 is responsible for providing a test signal TS, which is an analog signal, to the DUT 110 set on the DUT board 120. The DUT 110 processes the test signal TS to generate a test output signal TOS, which is also an analog signal. The ADC 160 converts the test output signal TOS into a digitalized test output signal DTOS. The DSP 150 then performs digital operations on the digitalized test output signal DTOS to determine whether the DUT 110 has passed the test or not.

The accuracy requirement on the test for checking the analog characteristics of the DUT 110 is quite strict, however. For example, it is sometimes required that a total harmonic distortion (THD) be lower than 0.005%. It is also sometimes required that an output noise voltage be lower than 0.000002 Vrms. In addition, the mixed-signal tester is an expensive test machine. An IC manufacturer may spend more than 30 thousand dollars for a single mixed-signal tester. Using a mixed-signal tester as a tool for testing on analog-signal ICs or mixed-signal ICs, which are mass-produced, involves wasting immense testing time, and the testing cost will be high.

### SUMMARY OF THE INVENTION

One of the objectives of the present invention is therefore to provide a circuit testing apparatus that lowers the overall testing cost and increases the testing efficiency.

The present invention discloses a circuit testing apparatus for testing a device under test. The circuit testing apparatus comprises a signal transformation module, a meter, and a logic tester. The signal transformation module is coupled to the device under test and converts an analog output signal generated by the device under test into a DC signal. The meter is coupled to the signal transformation module and measures the DC signal to generate a digital measuring result. The logic tester is coupled to the meter and determines a test result for the device under test according to the digital measuring result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a conventional circuit testing structure for testing mass-produced ICs.

FIG. 2, FIG. 4, and FIG. 5 show circuit-testing apparatus according to embodiments of the present invention.

FIG. 3 shows an exemplary embodiment of the signal transformation module of FIG. 2.

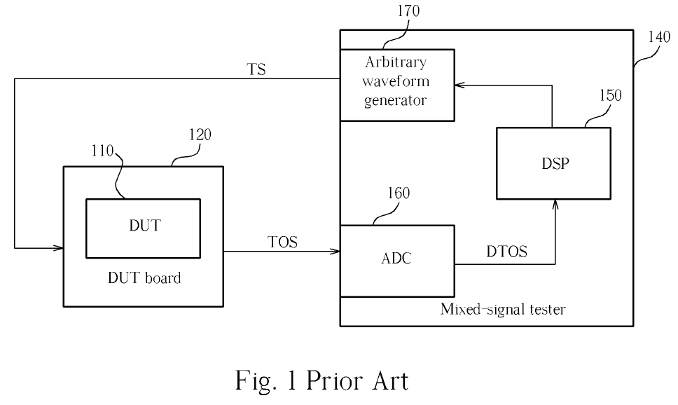

### DETAILED DESCRIPTION

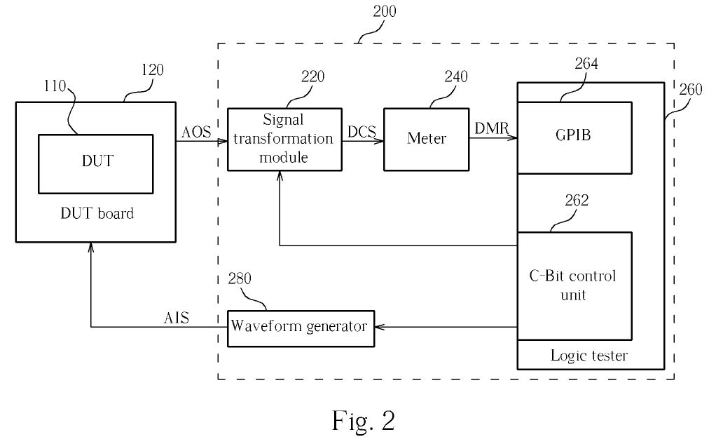

Please refer to FIG. 2. FIG. 2 shows a circuit testing apparatus according to an embodiment of the present invention. The circuit testing apparatus 200 of this embodiment is for testing a device under test (DUT) 110. For example, the DUT 110 may be an analog-signal IC or a mixed-signal IC set on a DUT board 120.

The circuit testing apparatus 200 of this embodiment comprises a signal transformation module 220, a meter 240, a logic tester 260, and a waveform generator 280. The logic tester 260 is a test machine capable of performing digital operations. Aside from circuitry for performing digital operations, the logic tester 260 further comprises a continuous built-in test (C-Bit) control unit 262. Through the C-Bit control unit 262, the logic tester 260 controls the operations of the signal transformation module 220 and the waveform generator 280 according to the test requirements. In addition, the logic tester 260 further comprises a general-purpose interface bus (GPIB) 264, which allows the logic tester 260 to receive a digital measuring result DMR from the meter 240.

The waveform generator 280 is controlled by the logic tester 260 and provides an analog input signal AIS to the DUT 110 set on the DUT board 120. The DUT 110 processes the analog input signal AIS to generate an analog output signal AOS. The signal transformation module 220 converts the analog output signal AOS into a DC signal DCS, which may be a DC voltage or a DC current. The meter 240 measures the DC signal DCS to generate a digital measuring result DMR, which digitally represents the voltage or current level of the DC signal DCS. Finally, the logic tester 260 determines a test result for the DUT 110 according to the digital measuring result DMR.

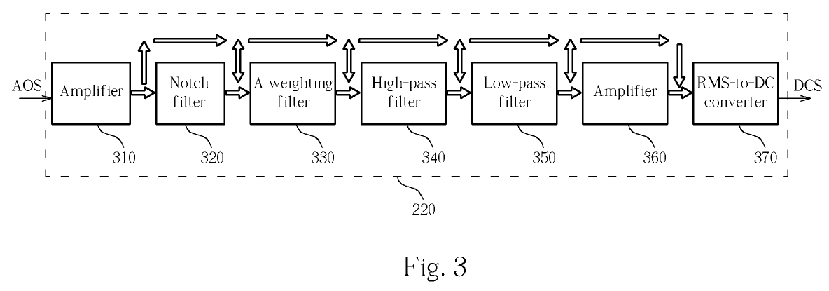

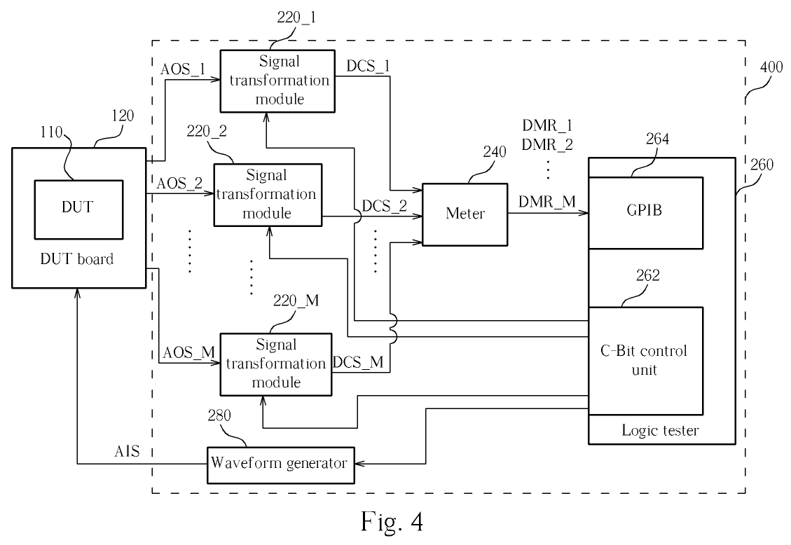

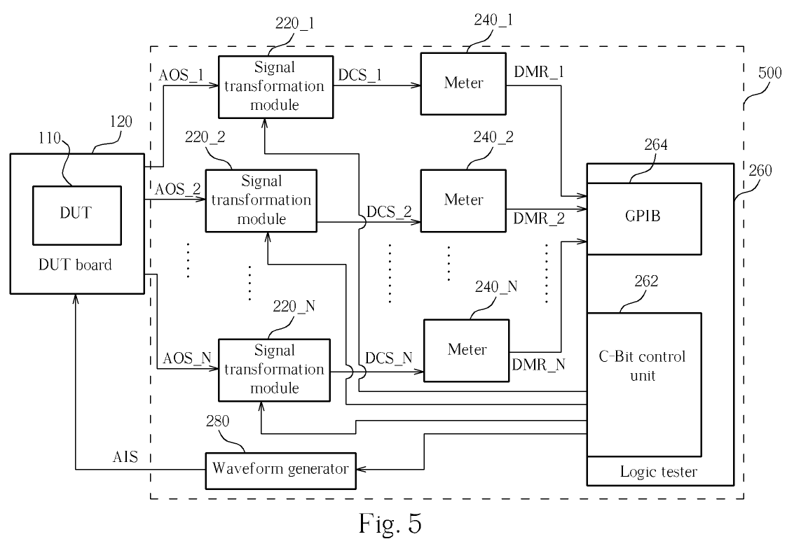

The signal transformation module 220 is responsible for converting an analog signal into a DC signal. For example, the signal transformation module 220 may comprise component(s) selected from a component group consisting of amplifiers, Notch filters, A weighting filters, high-pass filters, low-pass filters, and RMS-to-DC converters. FIG. 3 shows an exemplary embodiment of the signal transformation module 220 of FIG. 2. In this exemplary embodiment, the signal transformation module 220 comprises an amplifier 310, a Notch filter 320, an A weighting filter 330, a high-pass filter 340, a low-pass filter 350, an amplifier 360, and an RMS-to-DC converter 370 in turn. Please note that the order of the aforementioned components only serves as an example, and should not be treated as a limitation of the present invention. In addition, the signal transformation module 220 can also include other components that are not mentioned above. Furthermore, according to the test requirements, one or more components of the signal transformation module 220 can be selectively bypassed.

For example, when performing a noise test on the DUT 110, the Notch filter 320, the high-pass filter 340, and the low-pass filter 350 can be bypassed. With the amplifier 310, which is used to provide +40 dB signal amplifying, the Aweighting filter 330, and the RMS-to-DC converter 370, the DC signal DCS can be generated according to the analog output signal AOS. After the meter 240 measures the DC signal DCS to generate the digital measuring result DMR, the logic tester 260 can accordingly determine a noise test result for the DUT 110.

In another example, when performing a total harmonic distortion (THD) test on the DUT 110, the amplifier 310, the Notch filter 320, the Aweighting filter 330, the high-pass filter 340, the low-pass filter 350, and the amplifier 360 can be bypassed while only the RMS-to-DC converter 370 is used to convert the analog output signal AOS into the DC signal DCS. Assume that the digital measuring result DMR generated by the meter 240 is A under this situation. Then, the A weighting filter 330 is bypassed while the amplifier 310 is utilized to provide +20 dB signal amplifying. In addition, the Notch filter 320 is utilized to perform notch filtering with −80 dB signal amplifying and a 1 kHz notch frequency; the high-pass filter 340 is utilized to perform high-pass filtering with a 400 Hz pass band frequency; the low-pass filter 350 is utilized to perform low-pass filtering with a 30 kHz pass band frequency; the amplifier 360 is utilized to provide +40 dB signal amplifying; and the RMS-to-DC converter 370 is utilized to generate the DC signal DCS. Assume the digital measuring result DMR generated by the meter 240 is B under this situation. After the values A and B are obtained, the logic tester 260 can determine the THD (%) as follows:

$$THD ( \% ) = \frac{\sqrt{{H}_{2}^{2} + {H}_{3}^{2} + … + {H}_{N}^{2}}}{\sqrt{{H}_{1}^{2}}} \times 100 = \frac{B}{A} \times 100$$

When more than one channel of the DUT 110 is going to be tested, the multi-channel testing structures shown in FIG. 4 and FIG. 5 can be used. In the embodiment shown in FIG. 4, a circuit testing apparatus 400 comprising M signal transformation modules 220_1˜220_M is proposed, where M is an integer larger than 1. In the circuit testing apparatus 400, a signal transformation module 220_{—}m is used to convert an analog output signal AOS_m generated by the DUT 110 into a DC signal DCS_m, where m is an integer between 1 and M. The meter 240 measures the DC signals DCS_1, . . . , and DCS_M to generate digital measuring results DMR_1, . . . , and DMR_M respectively. For example, the meter 240 utilizes the digital measuring results DMR_m to digitally represent the voltage or current level of the DC signal DCS_m. Finally, the logic tester 260 determines a test result for the DUT 110 according to the digital measuring result DMR_1˜DMR_M.

In the embodiment shown in FIG. 5, a circuit testing apparatus 500 comprising N signal transformation modules 220_1˜220_N and N meter 240_1˜240_N is proposed, where N is an integer larger than 1. In the circuit testing apparatus 500, a signal transformation module 220_{—}n is used to convert an analog output signal AOS_n generated by the DUT 110 into a DC signal DCS_n, where n is an integer between 1 and N. A meter 240_n then measures the DC signals DCS_n to generate a digital measuring result DMR_n, which may represent the voltage or current level of the DC signal DCS_n. Finally, the logic tester 260 determines a test result for the DUT 110 according to the digital measuring result DMR_1_DMR_N.

In the embodiments of the present invention, a signal transformation module is utilized to convert an analog output signal generated by a DUT into a DC signal. A meter and a logic tester can be used to determine a test result for the DUT. No mixed-signal tester is required in the embodiments of the present invention. Since the cost of the mixed-signal tester is much more expensive than that of the meter and the logic tester, the overall cost of each of the embodiments of the present invention will be much lower than that of the prior art. In addition, a lot of testing time can be saved by the testing structures proposed by the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A circuit testing apparatus for testing a device under test (DUT), the circuit testing apparatus comprising:
a signal transformation module, coupled to the DUT, for converting an analog output signal generated by the DUT into a DC signal;
a meter, coupled to the signal transformation module, for measuring the DC signal to generate a digital measuring result; and
a logic tester, coupled to the meter, for determining a test result for the DUT according to the digital measuring result.

2. The circuit testing apparatus of claim 1, wherein the signal transformation module comprises component(s) selected from a component group consisting of amplifiers, Notch filters, A weighting filters, high-pass filters, low-pass filters, and RMS-to-DC converters.

3. The circuit testing apparatus of claim 1, wherein the meter measures the voltage level of the DC signal to generate the digital measuring result.

4. The circuit testing apparatus of claim 1, wherein the meter measures the current level of the DC signal to generate the digital measuring result.

5. The circuit testing apparatus of claim 1, wherein the logic tester utilizes a general-purpose interface bus (GPIB) to receive the digital measuring result from the meter.

6. The circuit testing apparatus of claim 1, further comprising:
a waveform generator, coupled to the DUT, for providing an analog input signal to the DUT;
wherein the DUT generates the analog output signal according to the analog input signal.

7. The circuit testing apparatus of claim 6, wherein the logic tester utilizes a C-Bit control unit to control the signal transformation module and the waveform generator while testing the DUT.

8. The circuit testing apparatus of claim 1, wherein the DUT comprises an analog-signal IC or a mixed-signal IC.
